(19) United States
(12) Patent Application Publication
(10) Pub. No.: US 2026/0183807 A1
(43) Pub. Date: Jul. 2, 2026

(54) CHEMICAL LIQUID SUPPLY APPARATUS AND CHEMICAL LIQUID EXCHANGE METHOD

(71) Applicant: SEMES CO., LTD., Cheonan-si (KR)

(72) Inventors: Yong Hoon HONG, Seoul (KR); Jin Ah HAN, Cheonan-si (KR); Boo Seok YANG, Busan (KR); Eon Jun PARK, Busan (KR); Dong Uk LEE, Seoul (KR); Hyeon Suk PARK, Cheonan-si (KR)

(73) Assignee: SEMES CO., LTD., Cheonan-si (KR)

(21) Appl. No.: 19/434,210

(22) Filed: Dec. 29, 2025

(30) Foreign Application Priority Data
Dec. 31, 2024 (KR) 10-2024-0202453

(51) Int. Cl. B08B 9/08; H10P 72/00

(52) U.S. Cl. CPC B08B 9/08; H10P 72/0414; B08B 2209/08

(57) ABSTRACT

Disclosed is a liquid exchange method in a liquid supply apparatus. The liquid exchange method in a liquid supply apparatus including a recovery tank, a sub-tank, a main tank, and a pre-tank includes: (a) a liquid exchange operation of the main tank and the sub tank; (b) a flushing operation of the recovery tank; and (c) a liquid exchange operation of the pre-tank, in which in the operation (a), a liquid supply is switched to a double tank operation mode in which a liquid is supplied to a substrate processing apparatus using only the recovery tank and the pre-tank as the pre-tank is switched to a main supply tank.

### CROSS-REFERENCE TO RELATED APPLICATION

This application claims priority to and the benefit of Korean Patent Application No. 10-2024-0202453 filed in the Korean Intellectual Property Office on Dec. 31, 2024, the entire contents of which are incorporated herein by reference.

### TECHNICAL FIELD

The present invention relates to a chemical supply apparatus and a chemical exchange method.

### BACKGROUND ART

Contaminants, such as particles, organic pollutants, and metal pollutants, remaining on the surface of the substrate greatly affect the characteristics and production yield of semiconductor devices. For this reason, a cleaning process of removing various pollutants attached to the surface of the substrate is very important in a semiconductor manufacturing process, and a process of cleaning the substrate is performed before and after each unit process of manufacturing a semiconductor. A process for removing such foreign substances includes a cleaning process using pure water or a chemical.

The chemical used in the substrate cleaning process may be recovered for reuse. The chemical recovered from the substrate processing unit is directly supplied to the chemical storage tank or recovered to a separate recovery storage tank and then supplied to the chemical storage tank. The recovered chemical in the chemical storage tank is supplied to the substrate processing unit and reused.

However, as the number of times of reuses of the chemical increases, there is a problem that the concentration of the chemical deviates from the reference concentration and that fine particles remain in the chemical. Accordingly, when the life time of the chemical is reached or the concentration of the chemical changes, all remaining chemicals are discharged and exchanged for new chemicals.

However, as the concentration of the new chemical filled in the tank and the remaining chemical remaining in the tank and the pipe (circulation line) are mixed, the concentration of the new chemical is distorted, resulting in a change in process performance.

For example, when the chemical is continuously reused in the process of etching the TiN film of the substrate, Ti ions are dissolved in the chemical. When the chemical in a state of high Ti ions is simply liquid-exchanged, not only defects due to lifetime, but also there is a disadvantage in that the stability of the chemical is deteriorated as the chemical with high Ti ions and the new chemical meet and dilute. (Ti ions are factors that decompose H₂O₂ and affect the TiN etching rate.)

Therefore, when the chemical is reused a certain number of times, it is necessary to supplement the chemical or to discharge all the remaining chemical and replace the remaining chemical with a new chemical. In this case, the chemical discharge time, supply time, and chemical temperature and concentration stabilization time are required to exchange the chemical in the chemical storage tank, resulting in a temporary suspension of the supply of the chemical to a substrate processing unit.

### SUMMARY OF THE INVENTION

The present invention has been made in an effort to provide a chemical supply apparatus and a chemical exchange method capable of exchanging a chemical in a tank with a new chemical without interrupting the supply of a chemical to a substrate processing apparatus.

The objectives of the present disclosure are not limited thereto and other objectives not stated herein may be clearly understood by those skilled in the art from the following description.

An exemplary embodiment of the present disclosure, a liquid exchange method in a liquid supply apparatus including a recovery tank, a sub-tank, a main tank, and a pre-tank, the liquid exchange method comprising: (a) a liquid exchange operation of the main tank and the sub tank; (b) a flushing operation of the recovery tank; and (c) a liquid exchange operation of the pre-tank, wherein in the operation (a), a liquid supply is switched to a double tank operation mode in which a liquid may be supplied to a substrate processing apparatus using only the recovery tank and the pre-tank as the pre-tank is switched to a main supply tank.

According to the exemplary embodiment of the present invention, wherein the operation (a) may include: a flushing operation of draining a chemical contained in the main tank and the sub tank during the double tank operation mode, injecting a flushing chemical into each tank and circulating the flushing chemical, and then draining the flushing chemical; and a liquid preparation operation of supplying a new chemical to the main tank and the sub tank.

According to the exemplary embodiment of the present invention, wherein in the operation (b), the liquid supply may be switched to a single tank operation mode in which the pre-tank alone supplies the liquid to the substrate processing apparatus.

According to the exemplary embodiment of the present invention, wherein the operation (b) further may include a liquid preparation operation of supplying a new chemical to the recovery tank after the flushing of the recovery tank is completed.

According to the exemplary embodiment of the present invention, wherein in the operation (c), the liquid supply is switched to a three tank operation mode in which the main tank may be switched to a main supply tank, and the liquid is supplied to the substrate processing apparatus using the main tank, the sub tank, and the recovery tank.

According to the exemplary embodiment of the present invention, wherein when the operation (b) is completed, the three tank operation mode may be switched regardless of the start of the operation (c).

According to the exemplary embodiment of the present invention, wherein the operation (c) may include: a flushing operation of draining the chemical contained in the pre-tank, injecting a flushing chemical into the pre-tank and circulating the flushing chemical, and then draining the flushing chemical; and a liquid preparation operation of supplying a new chemical to the pre-tank.

According to the exemplary embodiment of the present invention, wherein the operation (c) proceeds after the completion of the operation (b) or immediately before a lifetime of the chemical may be reached.

According to the exemplary embodiment of the present invention, wherein in the double tank operation mode, the chemical used in the substrate processing apparatus is recovered to the recovery tank, and in the single tank operation mode, the chemical used in the substrate processing apparatus is not recovered to the recovery tank and is treated as wastewater, and the flushing chemical may be the same chemical as the new chemical.

An exemplary embodiment of the present disclosure, a liquid supply apparatus for supplying a chemical to a substrate processing apparatus, the liquid supply apparatus comprising: a first tank to which a chemical used in the substrate processing apparatus is recovered; a second tank for receiving the chemical from the first tank; a third tank for receiving the chemical from the second tank and connected with a main circulation line for supplying the chemical to the substrate processing apparatus; a fourth tank for supplying a chemical to the substrate processing apparatus instead of the third tank during a liquid exchange of the first tank, the second tank, and the third tank; a chemical supply source for supplying a flushing chemical and a chemical to each of the first tank, the second tank, the third tank, and the fourth tank; and a controller may be configured to control the tanks and the chemical supply source to perform a double tank operation mode in which the chemical may be supplied to the substrate processing apparatus using only the first tank and the fourth tank when the liquid is exchanged in the second tank and the third tank.

According to the exemplary embodiment of the present invention, wherein the controller may be configured to control the tanks and the chemical supply source to perform a single tank operation mode in which the chemical is supplied to the substrate processing apparatus using only the fourth tank when the liquid exchange is completed in the second tank and the third tank.

According to the exemplary embodiment of the present invention, wherein the controller may be configured to control the tanks and the chemical supply source to perform flushing of the first tank in the single tank operation mode.

According to the exemplary embodiment of the present invention, wherein the controller may be configured to control the tanks and the chemical supply source to perform a three tank operation mode in which the chemical is supplied to the substrate processing apparatus using the first tank, the second tank, and the third tank when the flushing of the first tank is completed.

According to the exemplary embodiment of the present invention, wherein the first tank may include: a first circulation line for chemical circulation in the tank; and first liquid supplement lines branched from the first circulation line to supply a liquid to the second tank and the fourth tank, and the second tank includes: a second circulation line for chemical circulation in a tank; and a second liquid supplement line branched from the second circulation line to supply a liquid to the third tank.

According to the exemplary embodiment of the present invention, wherein the third tank may include: a third circulation line for chemical circulation in a tank; and a supply circulation line connected to a supply line of the substrate processing apparatus, and the fourth tank includes: a fourth circulation line for chemical circulation in a tank; and a sub-supply line connected to the supply circulation line.

According to the exemplary embodiment of the present invention, wherein the flushing chemical supplied from the chemical supply source to each tank may be the same chemical as the chemical.

According to the exemplary embodiment of the present invention, wherein the controller may configured to control a flushing process comprising injection, circulation, and drainage of the flushing liquid during the liquid exchange of the tanks to be performed multiple times.

An exemplary embodiment of the present disclosure, a liquid exchange method in a liquid supply apparatus including a recovery tank to which a chemical used in a substrate processing apparatus is recovered, a sub-tank for receiving the chemical from the recovery tank, a main tank for receiving the chemical from the sub-tank and supplying the chemical to the substrate processing apparatus, and a pre-tank for supplying the chemical to the substrate processing apparatus instead of the main tank during liquid exchange of the tanks, the liquid exchange method including: (a) a liquid exchange operation of the main tank and the sub tank; (b) a flushing operation of the recovery tank; and (c) a liquid exchange operation of the pre-tank, wherein in the operation (a), a liquid supply is switched to a double tank operation mode in which a liquid is supplied to a substrate processing apparatus using only the recovery tank and the pre-tank as the pre-tank is switched to a main supply tank, in the operation (b), the liquid supply is switched to a single tank operation mode in which the pre-tank alone supplies the liquid to the substrate processing apparatus, and in the operation (c), the liquid supply is switched to a three tank operation mode in which the main tank is switched to a main supply tank, and the liquid may be supplied to the substrate processing apparatus using the main tank, the sub tank, and the recovery tank.

According to the exemplary embodiment of the present invention, wherein the operation (a) includes: a flushing operation of draining a chemical contained in the main tank and the sub tank during the double tank operation mode, injecting a flushing chemical into each tank and circulating the flushing chemical, and then draining the flushing chemical; and a liquid preparation operation of supplying a new chemical to the main tank and the sub tank, and the operation (c) may include: a flushing operation of draining a chemical contained in the pre-tank, injecting a flushing chemical into the pre-tank and circulating the flushing chemical, and draining the flushing chemical; and a liquid preparation operation of supplying a new chemical to the pre-tank.

According to the exemplary embodiment of the present invention, wherein the operation (b) further includes a liquid preparation operation of supplying a new chemical to the recovery tank after flushing of the recovery tank is completed, when the operation (b) is completed, the three tank operation mode is switched regardless of the start of the operation (c), the operation (c) proceeds after the completion of the operation (b) or immediately before a lifetime of the chemical is reached, and in the double tank operation mode, the chemical used in the substrate processing apparatus is recovered to the recovery tank, and in the single tank operation mode, the chemical used in the substrate processing apparatus is not recovered to the recovery tank and may be treated as wastewater.

According to the exemplary embodiment of the present invention, it is possible to exchange a chemical in a tank with a new chemical without interrupting the supply of a chemical to a substrate processing apparatus.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram schematically illustrating a substrate processing apparatus according to an exemplary embodiment of the present invention.

FIG. 2 is a diagram schematically illustrating an exemplary embodiment of the liquid treating chamber of FIG. 3.

FIG. 3 is a diagram illustrating a chemical supply apparatus connected to the liquid treating chamber.

FIG. 4 is a flowchart illustrating a treatment liquid exchange method in the chemical supply apparatus.

FIGS. 5 to 13 are diagrams sequentially illustrating a treatment liquid exchange method.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜and ˜”, “just between ˜and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

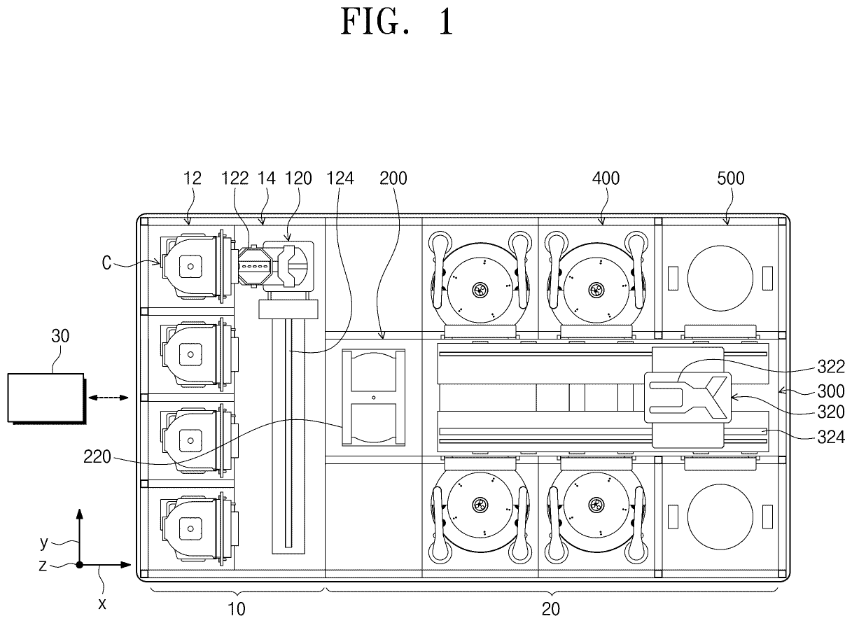

Hereinafter, an exemplary embodiment of the present invention will be described with reference to FIGS. 1 to 13.

FIG. 1 is a diagram schematically illustrating a substrate processing apparatus according to an exemplary embodiment of the present invention.

Referring to FIG. 1, a substrate processing apparatus includes an index module 10, a treating module 20, and a controller 30. When viewed from above, the index module 10 and the treating module 20 are disposed along one direction. Hereinafter, the direction in which the index module 10 and the treating module 20 are disposed is referred to as a first direction X, and when viewed from above, a direction perpendicular to the first direction X is referred to as a second direction Y, and a direction perpendicular to both the first direction X and the second direction Y is referred to as a third direction Z.

The index module 10 transfers a substrate W from a container C in which the substrate W is accommodated to the treating module 20, and makes the substrate W, which has been completely processed in the treating module 20, be accommodated in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. The plurality of load ports 12 may be provided, and may be disposed in the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is the second direction Y is provided within the index frame 14, and the index robot 120 may be provided to be movable on the guide rail 124. The index robot 120 includes a hand 122 on which the substrate W is placed, and the hand 122 may be provided to be movable forward and backward, rotatable about the third direction Z, and movable along the third direction Z. A plurality of hands 122 are provided to be spaced apart in the vertical direction, and the hands 122 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treating process of liquid-treating the substrate W by supplying a liquid onto the substrate W. The drying chamber 500 performs a drying process for removing a liquid remaining on the substrate W. The transfer chamber 300 transfers the substrate W between the buffer unit 200, the liquid treating chamber 400, and the drying chamber 500.

The transfer chamber 300 may be provided so that a longitudinal direction is the first direction X. The buffer unit 200 may be disposed between the index module 10 and the transfer chamber 300. The liquid treating chamber 400 and the drying chamber 500 may be disposed on a side portion of the transfer chamber 300. The liquid treating chamber 400 and the transfer chamber 300 may be disposed in the second direction Y. The drying chamber 500 and the transfer chamber 300 may be disposed in the second direction Y. The buffer unit 200 may be located at one end of the transfer chamber 300.

According to an example, the liquid treating chambers 400 may be disposed on opposite sides of the transfer chamber 300, the drying chambers 500 may be disposed on opposite sides of the transfer chamber 300, and the liquid treating chambers 400 may be disposed closer to the buffer unit 200 than the drying chambers 500. At one side of the transfer chamber 300, the liquid treating chambers 400 may be provided in an array of A×B (each of A and B is 1 or a natural number larger than 1) in the first direction X and the third direction Z. Further, at one side of the transfer chamber 300, the drying chambers 500 may be provided in a number of C×D (C and D are each 1 or a natural number larger than 1) may be provided along each of the first direction X and the third direction Z. Unlike the above description, only the liquid treating chambers 400 may be provided at one side of the transfer chamber 300, and only the drying chambers 500 may be provided at the other side thereof.

The transfer chamber 300 includes a transfer robot 320. A guide rail 324 having a longitudinal direction in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward, rotatable about the third direction Z, and movable along the third direction Z. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

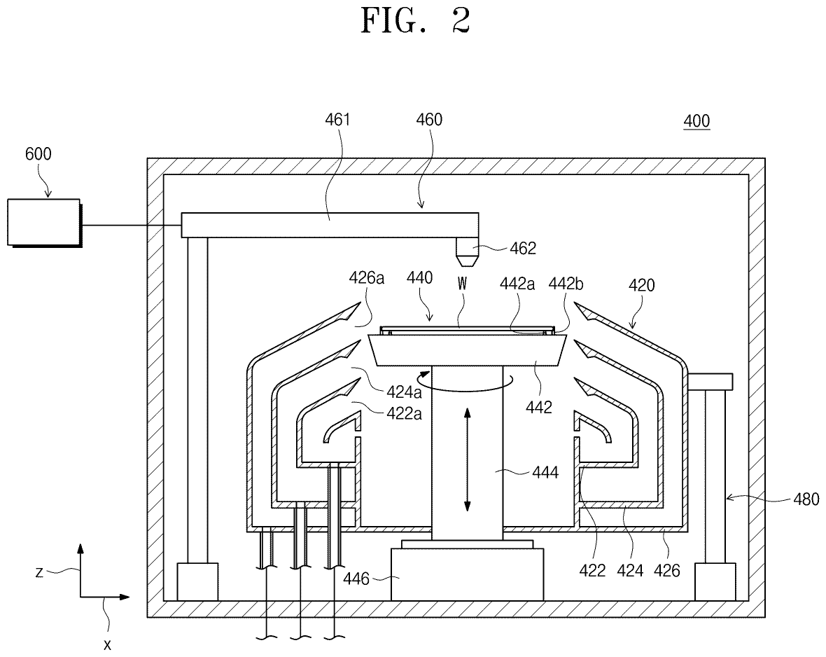

FIG. 2 is a diagram schematically illustrating an exemplary embodiment of the liquid treating chamber of FIG. 1.

Referring to FIG. 2, the liquid treating chamber 400 includes a housing 410, a cup 420, a support unit 440, a liquid injection unit 460, and a lifting unit 480.

The housing 410 may have an inner space in which the substrate W is processed. The housing 410 may have a substantially hexahedral shape. For example, the housing 410 may have a substantially rectangular parallelepiped shape. Further, an opening (not illustrated) through which the substrate W enters and exits is formed in the housing 410. Also, a door (not illustrated) for selectively opening and closing the opening may be installed in the housing 410.

The cup 420 may have a cylindrical shape with an open top. The cup 420 has a treatment space, and the substrate W is liquid-treated in the treatment space. The support unit 440 supports the substrate W in the treatment space. The liquid injection unit 460 supplies the treatment liquid onto the substrate W supported by the support unit 440. The treatment liquid may be provided in a plurality of types, and may be sequentially supplied onto the substrate W. The lifting unit 480 adjusts a relative height between the cup 420 and the support unit 440.

According to an example, the cup 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 440. As the liquid treatment process proceeds, the treatment liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a drive shaft 444. An upper surface of the support plate 442 may be provided in a generally circular shape, and may have a diameter larger than a diameter of the substrate W. Further, a support pin 442a supporting the rear surface of the substrate W is provided at the center of the support plate 442, and the upper end of the support pin 442a is provided to protrude from the support plate 442 so that the substrate W is spaced apart from the support plate 442 by a predetermined distance. A chuck pin 442b is provided at an edge portion of the support plate 442. The chuck pin 442b is provided to protrude upward from the support plate 442, and supports the side portion of the substrate W so that the substrate W does not deviate from the support unit 440 when the substrate W is rotated. The drive shaft 444 is driven by a driver 446, is connected to the center of the bottom surface of the substrate W, and rotates the support plate 442 about its central axis.

According to an example, the liquid injection unit 460 may include a nozzle 462. The nozzle 462 may discharge a treatment liquid to the substrate W. The treatment liquid may be a chemical, rinse liquid or an organic solvent. The chemical may be a chemical having strong acid or strong base properties. In addition, the liquid injection unit 460 may include a plurality of nozzles 462, and the nozzle 462 may discharge different types of treatment liquids, respectively. For example, one of the nozzles 462 may discharge a chemical, another one of the nozzles 462 may discharge the rinse liquid, and another one of the nozzles 462 may discharge the organic solvent. The liquid injection unit 460 receives a treatment liquid (chemical) from the chemical supply apparatus 600.

The present invention may be applied to a wet etching process or a cleaning process of removing a film on the surface of a substrate, and various treatment liquids may be used for this process. The treatment liquid that may be used in the present invention may include at least one material selected from hydrofluoric acid (HF), sulfuric acid (H₃SO₄), hydrogen peroxide (H₂O₂), nitric acid (HNO₃), phosphoric acid (H₃PO₄), ozone water, SC-1 solution (a mixture of ammonium hydroxide (NH₄OH), hydrogen peroxide (H₂O₂), and water) and the like, and may include treatment liquids of various materials that may be used in the substrate processing process.

The lifting unit 480 moves the cup 420 in the vertical direction. By the vertical movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 may be fixedly installed, and the lifting unit 480 may move the support unit 440 in the vertical direction.

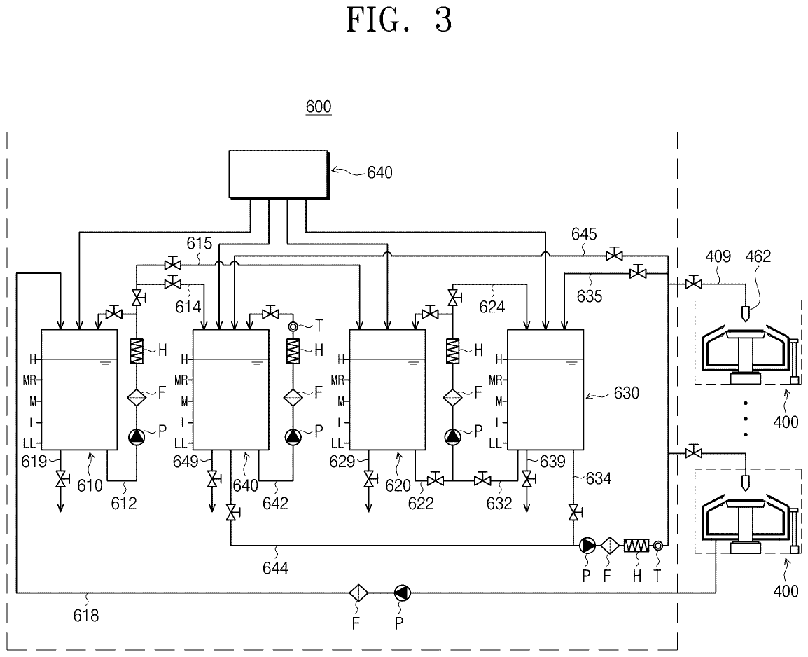

FIG. 3 is a diagram illustrating a chemical supply apparatus connected to the liquid treating chamber.

Referring to FIG. 3, the chemical supply apparatus 600 supplies a chemical used for processing a substrate to the liquid treating chamber 400. The chemical supply apparatus 600 may be provided to supply a chemical to the plurality of liquid treating chambers 400. The liquid treating chamber 400 may perform a process of etching the TiN film of the substrate. When the chemical is continuously reused in the process of etching the TiN film, the Ti ion concentration in the chemical increases. When the chemical having a high Ti ion concentration is mixed with a new chemical, stability of the chemical may be deteriorated. Therefore, a flushing process of removing the chemical remaining in each tank and the circulation line of the chemical supply apparatus device before supplying a new chemical is very important.

The chemical supply apparatus 600 may include a first tank 610, a second tank 620, a third tank 630, a fourth tank 640, a chemical supply source 660, and a controller 30. The controller 30 may control the first tank 610, the second tank 620, the third tank 630, the fourth tank 640, and the chemical supply source 650.

The first tank 610 is a recycling tank that receives and regenerates the chemical used in the liquid treating chamber 400, the second tank 620 is a sub-tank in which the fine temperature adjustment is performed on the chemical received from the first tank 620, the third tank 630 is a main tank of the chemical supply apparatus that receives a chemical from the second tank 620 and supplies the chemical to the liquid treating chamber 400, and the fourth tank 640 is a pre-tank for supplying a chemical to the liquid treating chamber 400 instead of the third tank when the liquid is exchanged in the third tank.

A recovery line 618 is connected to the liquid treating chamber 400 in the first tank 610. The chemical used in the liquid treating chamber 400 may be recovered to the first tank 610 through the recovery line 618. A pump P and a filter F may be installed on the recovery line 618.

The first tank 610 may be replenished with a new chemical so that the chemical recovered through the recovery line 618 may be reused, and through this, the chemical concentration may be corrected. The new chemical for correcting the chemical concentration may be received through the chemical supply source 650.

The first tank 610 may include a first circulation line 612, a first reuse supply line 614, and a second reuse supply line 615. The first circulation line 612 circulates the chemical stored in the first tank 610. A pump P, a filter F, and a heater H may be installed on the first circulation line 612. The chemical which has been regenerated in the first tank 610 may be provided to the second tank 620 or the fourth tank 640 through the first reuse supply line 814 or the second reuse supply line 815. A first drain line 619 is provided at a lower end of the first tank 610.

The second tank 620 stores the chemical supplied from the first tank 610. A fine temperature correction of the chemical is performed in the second tank 620. The second tank 620 may include a second circulation line 622 and a first supply line 624. The second circulation line 622 circulates the chemical stored in the second tank 620 for the chemical temperature correction. A pump P, a filter F, and a heater H may be installed on the second circulation line 622. The chemical of which temperature correction is completed in the second tank 620 may be provided to the third tank 630 through the first supply line 624. A second drain line 629 is provided at a lower end of the second tank 620.

The third tank 630 stores the chemical supplied from the second tank 620. The third tank 630 may include a third circulation line 632 and a supply circulation line 634. The third circulation line 632 circulates the chemical stored in the third tank 620. The third circulation line 632 may be connected to the second circulation line 622 to use the pump P, the filter F, and the heater H installed in the second circulation line 622. The pump P, the filter F, and the heater H installed in the second circulation line 622 may be used to internally circulate the chemical of the third tank 630. The third circulation line 632 may include a partial section of the second circulation line 622 in which the pump P, the filter F, and the heater H are installed, and the first supply line 624. A third drain line 639 is provided at a lower end of the third tank 630. The supply circulation line 634 may be provided with a pump P, a filter F, and a heater H. The supply circulation line 634 may include a return line 635. The chemical which is not supplied to the supply line 409 is returned to the third tank 630 through the return line 635. A supply line 409 of the liquid treating chamber 400 is connected to the supply circulation line 634. The supply line 409 may be connected to the nozzle 462 of the liquid injection unit 460 illustrated in FIG. 2.

The fourth tank 640 receives the chemical from the first tank 610 in a specific mode. The fourth tank 640 may include a fourth circulation line 642 and a supply circulation line 644. The fourth circulation line 642 circulates the chemical stored in the fourth tank 620. A fine temperature correction of the chemical is performed in the fourth tank 640. A pump P, a filter F, and a heater H may be installed on the fourth circulation line 642. A sensor T for measuring the concentration may be installed on the fourth circulation line 642. The chemical of which temperature correction is completed in the fourth tank 640 is provided to the supply line 409 of the liquid treating chamber 400 through the supply line 644. The supply line 644 may be connected to the supply circulation line 634. Accordingly, the chemical supply from the fourth tank 640 to the liquid treating chamber 400 utilizes the pump P, the filter F, and the heater H installed on the supply circulation line 634. A pre-return line 645 may be connected to the fourth tank 640. The pre-return line 645 may be connected to a rear end of the supply circulation line 634. Among the chemical supplied to the supply line 644, the unused chemical is returned to the fourth tank 640 through the pre-return line 645.

The valves installed in the first tank 610, the second tank 620, the third tank 630, and the fourth tank 640 may be controlled by the controller 30.

The treatment liquid supply source 640 may supply a flushing chemical for flushing the first tank 610, the second tank 620, the third tank 630, and the fourth tank 640 in a flushing mode. The flushing chemical may be the same liquid as the chemical used in the process. The chemical supply source 640 may supply the new chemical to each tank after completing the flushing mode.

The controller 30 may control the tanks 610, 620, 630, and 640 and the chemical supply source 650 to perform the flushing mode in which the chemical (existing chemical) accommodated in the first tank 610, the second tank 620, the third tank 630, and the fourth tank 640 is drained, the flushing chemical is injected into each of the tanks 610, 620, 630, and 640 and circulated, and then the flushing chemical is drained, and a liquid exchange mode in which a new chemical is supplied to each tank and is liquid-exchanged.

The controller 30 may set a drain time point of each of the tanks 610, 620, 630, and 640 and a flushing chemical injection and circulation operation differently in the flushing mode. In addition, when the flushing of each of the tanks 610, 620, 630, and 640 is completed, the controller 30 may control the valve installed in each of the drain lines 619, 629, 639, and 649 to drain the flushing chemical. The flushing mode including the flushing chemical injection, circulation, and drain of each of the tanks 610, 620, and 630 is preferably repeated at least once.

For example, the controller 30 may control the tanks and the chemical supply source 650 to perform a double tank operation mode for supplying the chemical to the liquid treating chamber 400 using only the first tank 610 and the fourth tank 640 when the liquid exchange is performed between the second tank 620 and the third tank 630. When the liquid exchange between the second tank 620 and the third tank 630 is completed, the controller may control the tanks and the chemical supply source 650 to perform a single tank operation mode for supplying the chemical to the liquid treating chamber 400 by the fourth tank 640 alone. The controller may control flushing of the first tank 610 in the single tank operation mode. When the flushing of the first tank 610 is completed, the controller may control the tanks and the chemical supply source 650 to perform a three tank operation mode of supplying the chemical to the liquid treating chamber 400 using the first tank 610, the second tank 620, and the third tank 630.

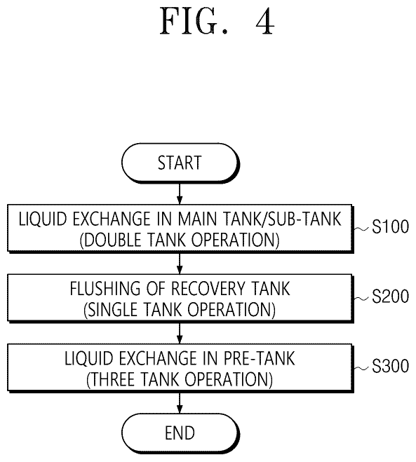

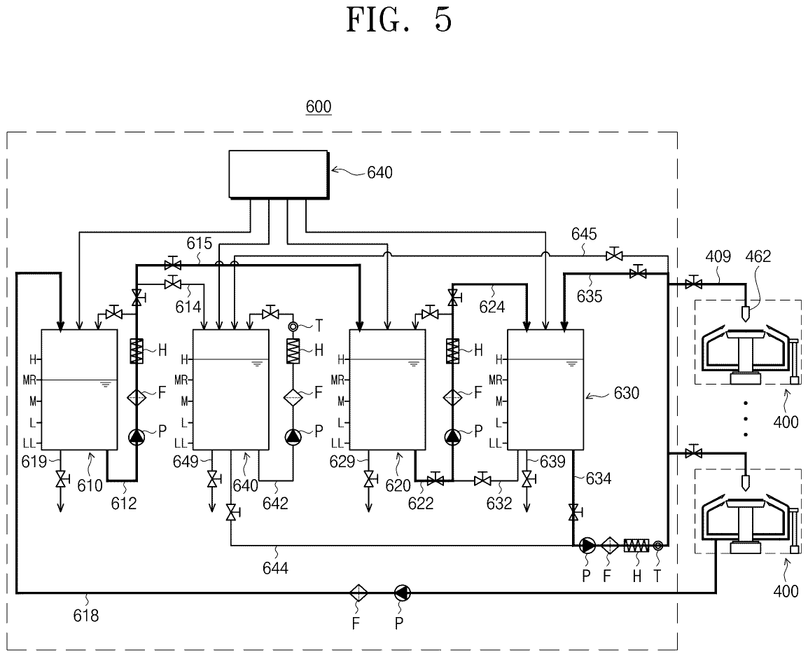

FIG. 4 is a flowchart illustrating a treatment liquid exchange method in the chemical supply apparatus, and FIGS. 5 to 13 are diagrams sequentially illustrating the treatment liquid exchange method.

Referring to FIGS. 4 to 13, the treatment liquid exchange method may include a liquid exchange operation S100 of the second tank 620 and the third tank 630, a flushing operation S200 of the first tank 610, and a liquid exchange operation S300 of the fourth tank 640. Immediately before the liquid exchange operation S100 of the second tank 620 and the third tank 630, the chemical is supplied to the liquid treating chamber 400 through the three tank mode (basic supply mode) using the first, second, and third tanks. In this case, a chemical to be supplied to the liquid treating chamber 400 is prepared in the fourth tank 640 (see FIG. 5).

The exchange of the treatment liquid may be performed before the chemical life time of the chemical supply apparatus is reached or when a concentration spec out of the chemical occurs. For example, when the chemical life time is 24 hours, the chemical exchange may be performed when the chemical life time remains 1 hour and 30 minutes. In the flushing operation, the same chemical as the chemical used in the process is used as the flushing chemical supplied to each tank. Accordingly, when the new chemical is supplied to each tank after flushing is completed, a distortion of the chemical concentration may be prevented.

The liquid exchange operation S100 of the second tank 620 and the third tank 630 may include a flushing operation and a chemical preparation operation.

In the flushing operation, the chemical contained in the second tank 620 and the third tank 630 is drained, and the flushing chemical is injected into the tank and then circulated, and the flushing chemical is drained.

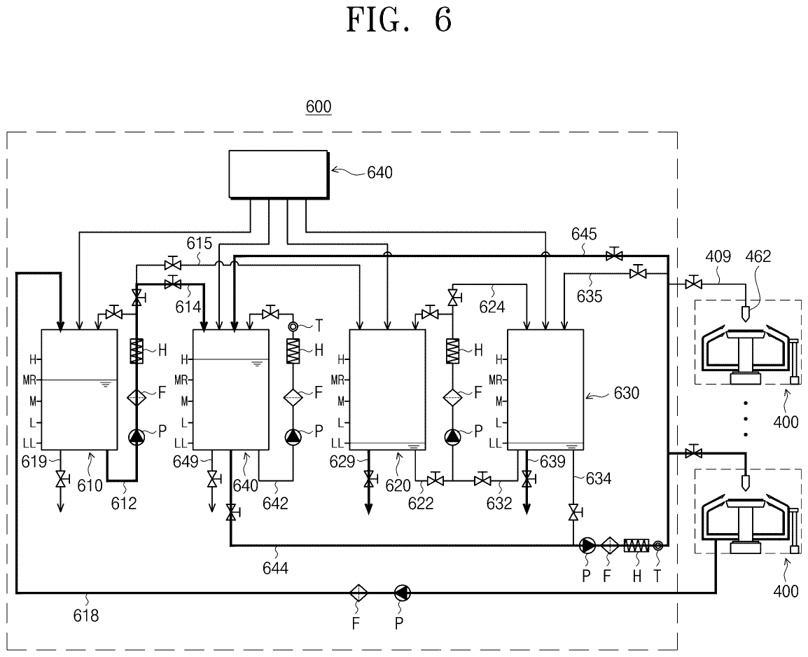

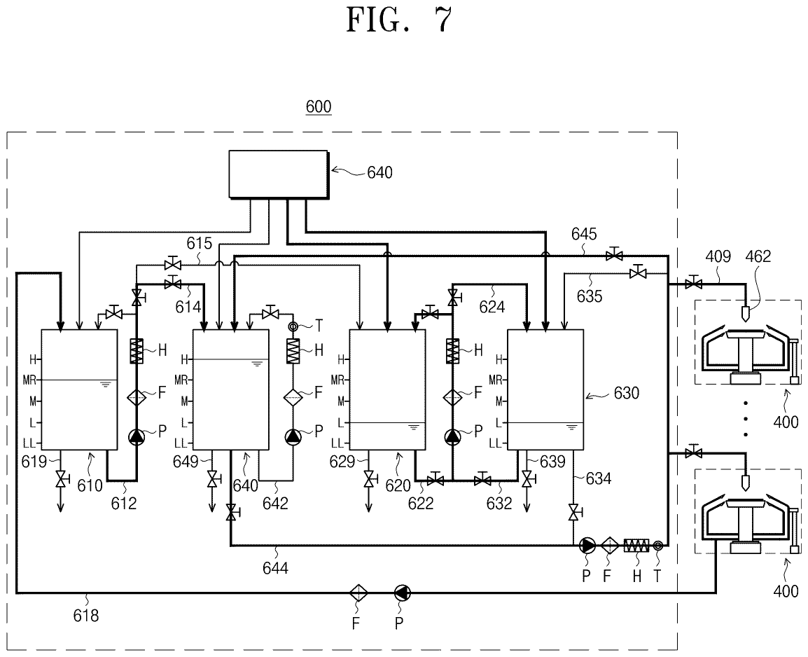

Specifically, first of all, the chemical of the second tank 620 and the third tank 630 is drained (see FIG. 6). When the chemical drains of the first tank 610 and the third tank 630 are completed, the flushing chemical is first injected into the third tank 630, and the flushing chemical is internally circulated through the third circulation line 632 connected to the third tank 630 (see FIG. 7). When the chemical drain of the second tank 620 is completed, the flushing chemical is injected into the empty second tank 620 (see FIG. 7). The flushing chemical of the second tank 620 is internally circulated (internal circulation) through the second circulation line 622 (see FIG. 7). For example, the time points at which the flushing chemical is injected into the second tank 620 and the third tank 630 may be the same. However, since the supply capacity of the chemical supply source 640 is limited, it is preferable that the flushing chemical is sequentially supplied for each tank. When the flushing of each of the second tank 620 and the third tank 630 is completed, the flushing chemical is drained from each tank.

For example, in the flushing operation, the flushing time of the third tank 630 may be set relatively longer than the flushing time of other tanks. In addition, in the flushing operation, the flushing chemical input to the third tank 630 may be set to be relatively larger than the flushing chemical input to the other tank 620. That is, since the third tank 630 includes a relatively longer circulation line than the second tank 620, the input amount of the flushing chemical and the flushing time were allocated relatively large and long, and the input of the flushing chemical was also allocated first.

Meanwhile, the flushing operation may be repeated 2 to 5 times to remove the residual chemical of the circulation line as much as possible. In particular, the number of times of the flushing operation may be set differently for each tank. In this way, a process margin may be secured by removing the residual chemical in the circulation line of each tank, and a fresh chemical may be prepared through Ti dilution discharge in the circulation line. The heater installed in each circulation line does not operate in the flushing operation.

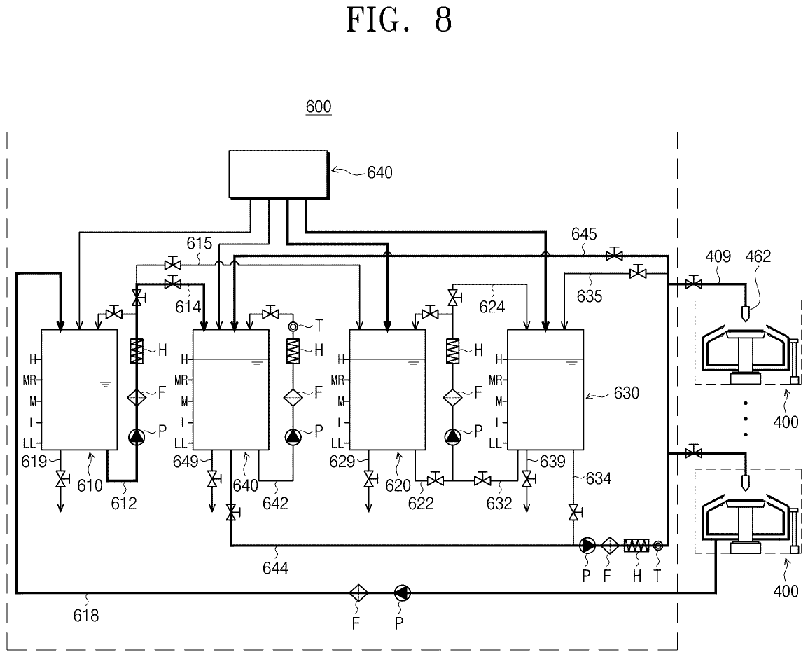

In the chemical preparation operation, after the flushing operation is completed, the new chemical is supplied to the second tank 620 and the third tank 630 (see FIG. 8). The new chemical is supplied from the chemical supply source 640. When the new chemical is supplied to the third tank 630, the (heater operation) temperature is adjusted while performing the internal circulation through the third circulation line 632, and when the new chemical is supplied to the third tank 630, the new chemical is circulated through the supply circulation line 634 (main circulation). When the flushing operation of the second tank 620 is completed, the new chemical is supplied to the second tank 620, and when the new chemical supply of the second tank 620 is completed, the internal circulation is performed through the second circulation line 622 (heater operation). The chemical preparation operation is an operation of preparing the chemical according to conditions (temperature and concentration) required for the process. In the present exemplary embodiment, it has been described that the new chemical is supplied from the third tank 630, but the present invention is not limited thereto.

During the liquid exchange operation S100 of the second tank 620 and the third tank 630, the chemical supply to the liquid treating chamber 400 is switched to the double tank operation mode. In the double tank operation mode, the fourth tank 640 is converted into a main supply tank and the liquid is supplied to the liquid treating chamber 400 using only the first tank 610 and the fourth tank 640. Accordingly, the liquid may be supplied to the liquid treating chamber 400 even during the liquid exchange of the tank.

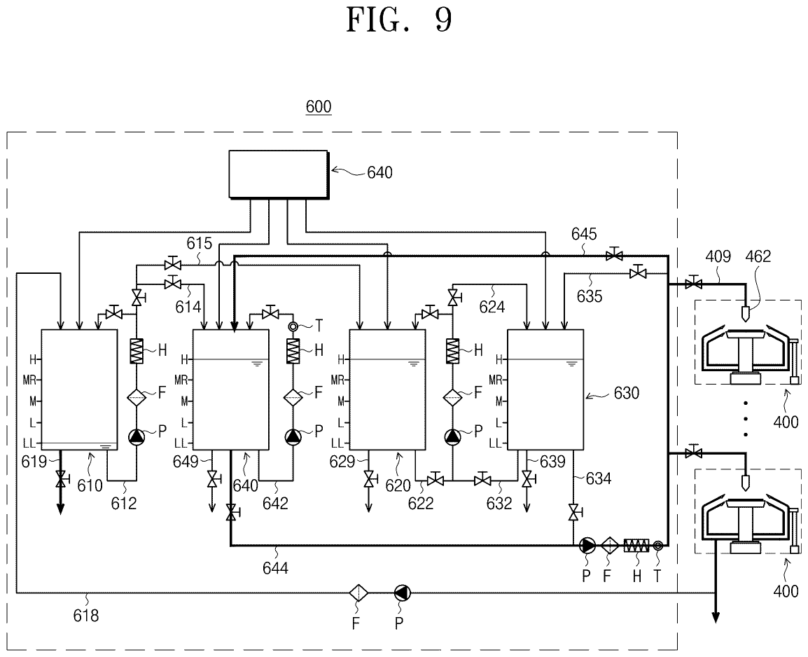

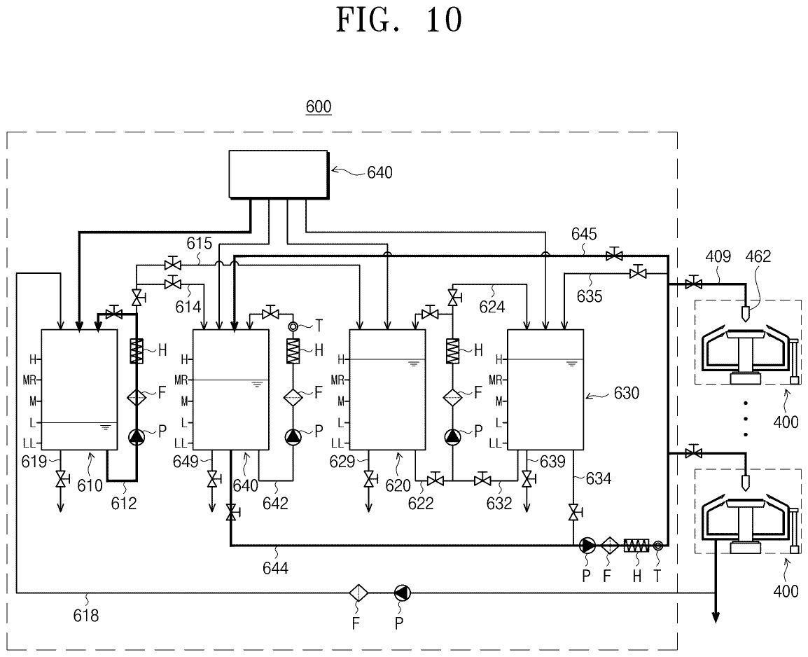

In the flushing operation S200 of the first tank 610, the chemical of the first tank 610 is drained (see FIG. 9). When the chemical drain of the first tank 610 is completed, the flushing chemical is first injected into the first tank 610, and the flushing chemical is internally circulated through the first circulation line 612 connected to the first tank 610 (see FIG. 10). When the flushing of the first tank 620 is completed, the flushing chemical is drained. Meanwhile, the flushing operation of the first tank 610 may optionally further include a chemical preparation operation of receiving a new chemical after the flushing is completed.

During the flushing operation S200 of the first tank 610, chemical supply to the liquid treating chamber 400 is switched to the single tank operation mode. In the single tank operation mode, the liquid is supplied to the liquid treating chamber 400 using only the fourth tank 640 (see FIG. 9 and FIG. 10).

In the double tank operation mode, the chemical used in the liquid treating chamber 400 is recovered to the first tank 610, and in the single tank operation mode, the chemical used in the liquid treating chamber 400 is not recovered to the first tank 610 and is treated as wastewater.

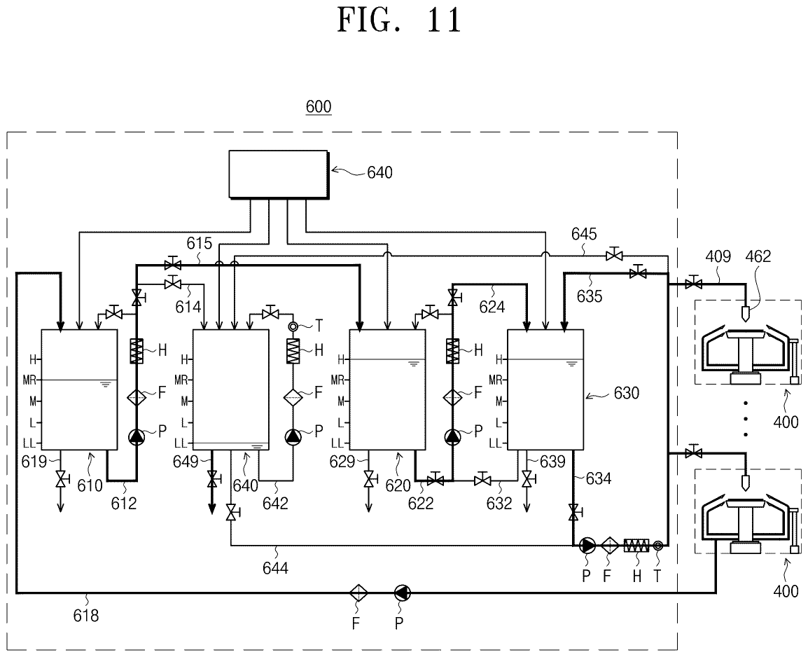

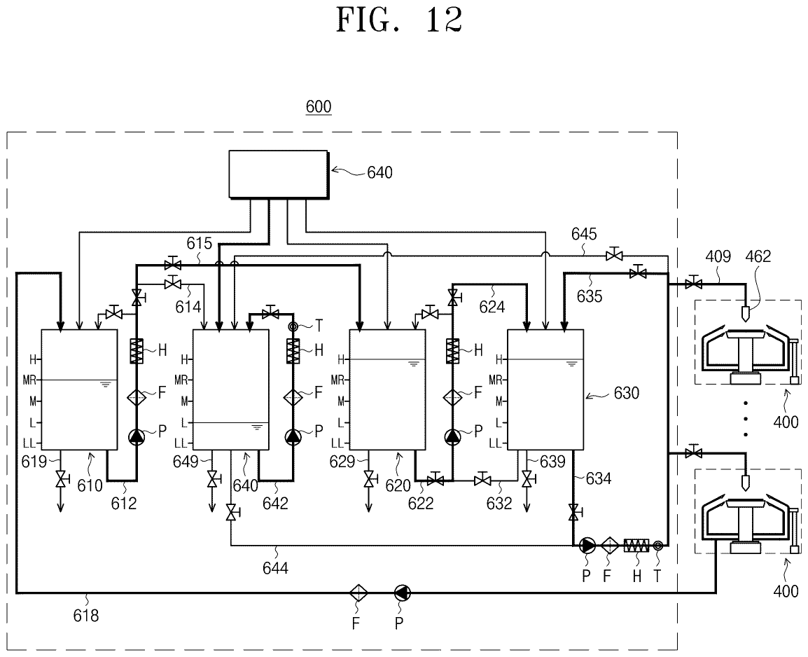

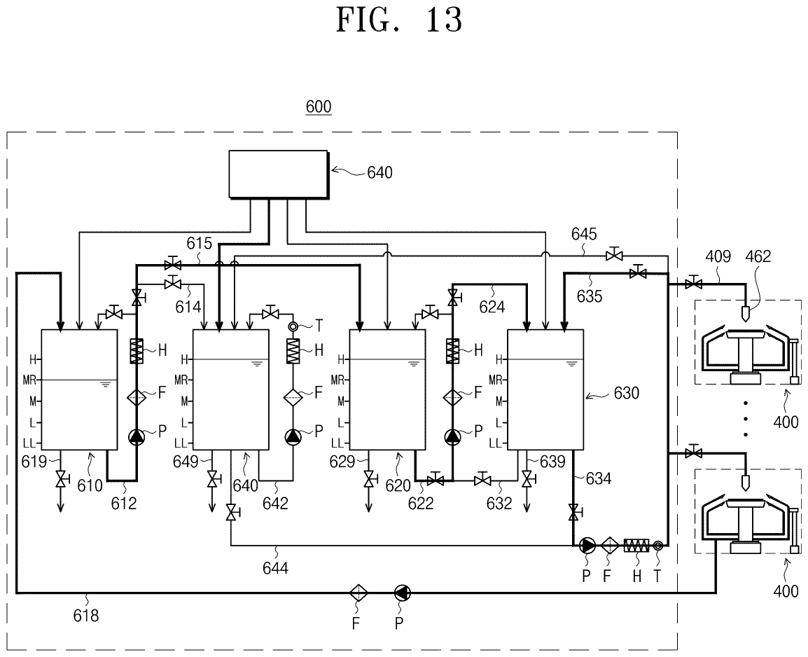

The liquid exchange operation S300 of the fourth tank 640 may include a flushing operation and a chemical preparation operation. In the flushing operation, the chemical contained in the fourth tank 640 is drained (see FIG. 11), the flushing chemical is injected into the corresponding tank and circulated, and then the flushing chemical is drained (see FIG. 12). In the chemical preparation operation, after the flushing operation is completed, the new chemical is supplied to the fourth tank 640 (see FIG. 13). The new chemical is supplied from the chemical supply source 640. When the new chemical is supplied to the fourth tank 640, the internal circulation is performed through the fourth circulation line 642 (heater operation).

The liquid exchange operation S300 of the fourth tank 640 may be selectively performed after the flushing of the first tank 610 or before the chemical lifetime reaches (1 hour and 30 minutes before). Preferably, the chemical preparation operation of the fourth tank 640 is performed before the chemical lifetime reaches, thereby minimizing the time for which the chemical waits in the tank.

While the liquid exchange operation S300 of the fourth tank 640 is in progress, the chemical supply to the liquid treating chamber 400 is switched to the three tank operation mode. In the three tank operation mode, the liquid is supplied to the liquid treating chamber 400 using the first tank 610, the second tank 620, and the third tank 630 while the third tank 630 is switched to the main supply tank. The switching from the single tank operation mode to the three tank operation mode is performed when the chemical in the fourth tank 640 reaches the lowest level and after the flushing of the first tank 610 is completed. That is, when the flushing operation of the first tank 610 is completed, the three tank operation mode may be switched regardless of the start of the liquid exchange operation of the fourth tank 640.

On the other hand, by first exchanging the liquid between the third tank 630 and the second tank 620 without liquid exchange between the third tank 630, the second tank 620, and the first tank 610 from the beginning, the chemical stored in the first tank 610 may be exhausted, and the chemical used for substrate processing may be reused as much as possible, thereby reducing the chemical treated in wastewater during liquid exchange.

As described above, the treatment liquid exchange method in the chemical supply apparatus sets the flushing operation and the chemical preparation operation of each tank differently, and during that time, the chemical is supplied from the fourth tank 640 to the liquid treating chamber 400, so that liquid exchange may be performed without interruption of the process.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A liquid exchange method in a liquid supply apparatus including a recovery tank, a sub-tank, a main tank, and a pre-tank, the liquid exchange method comprising:
(a) a liquid exchange operation of the main tank and the sub tank;
(b) a flushing operation of the recovery tank; and
(c) a liquid exchange operation of the pre-tank,
wherein in the operation (a), a liquid supply is switched to a double tank operation mode in which a liquid is supplied to a substrate processing apparatus using only the recovery tank and the pre-tank as the pre-tank is switched to a main supply tank.

2. The liquid exchange method of claim 1, wherein the operation (a) includes: a flushing operation of draining a chemical contained in the main tank and the sub tank during the double tank operation mode, injecting a flushing chemical into each tank and circulating the flushing chemical, and then draining the flushing chemical; and
a liquid preparation operation of supplying a new chemical to the main tank and the sub tank.

3. The liquid exchange method of claim 2, wherein in the operation (b), the liquid supply is switched to a single tank operation mode in which the pre-tank alone supplies the liquid to the substrate processing apparatus.

4. The liquid exchange method of claim 3, wherein the operation (b) further includes a liquid preparation operation of supplying a new chemical to the recovery tank after the flushing of the recovery tank is completed.

5. The liquid exchange method of claim 2, wherein in the operation (c), the liquid supply is switched to a three tank operation mode in which the main tank is switched to a main supply tank, and the liquid is supplied to the substrate processing apparatus using the main tank, the sub tank, and the recovery tank.

6. The liquid exchange method of claim 5, wherein when the operation (b) is completed, the three tank operation mode is switched regardless of the start of the operation (c).

7. The liquid exchange method of claim 4, wherein the operation (c) includes:
a flushing operation of draining the chemical contained in the pre-tank, injecting a flushing chemical into the pre-tank and circulating the flushing chemical, and then draining the flushing chemical; and
a liquid preparation operation of supplying a new chemical to the pre-tank.

8. The liquid exchange method of claim 7, wherein the operation (c) proceeds after the completion of the operation (b) or immediately before a lifetime of the chemical is reached.

9. The liquid exchange method of claim 2, wherein in the double tank operation mode, the chemical used in the substrate processing apparatus is recovered to the recovery tank, and in the single tank operation mode, the chemical used in the substrate processing apparatus is not recovered to the recovery tank and is treated as wastewater, and
the flushing chemical is the same chemical as the new chemical.

10-17. (canceled)

18. A liquid exchange method in a liquid supply apparatus including a recovery tank to which a chemical used in a substrate processing apparatus is recovered, a sub-tank for receiving the chemical from the recovery tank, a main tank for receiving the chemical from the sub-tank and supplying the chemical to the substrate processing apparatus, and a pre-tank for supplying the chemical to the substrate processing apparatus instead of the main tank during liquid exchange of the tanks, the liquid exchange method including:
(a) a liquid exchange operation of the main tank and the sub tank;
(b) a flushing operation of the recovery tank; and
(c) a liquid exchange operation of the pre-tank,
wherein in the operation (a), a liquid supply is switched to a double tank operation mode in which a liquid is supplied to a substrate processing apparatus using only the recovery tank and the pre-tank as the pre-tank is switched to a main supply tank,
in the operation (b), the liquid supply is switched to a single tank operation mode in which the pre-tank alone supplies the liquid to the substrate processing apparatus, and
in the operation (c), the liquid supply is switched to a three tank operation mode in which the main tank is switched to a main supply tank, and the liquid is supplied to the substrate processing apparatus using the main tank, the sub tank, and the recovery tank.

19. The liquid exchange method of claim 18, wherein the operation (a) includes: a flushing operation of draining a chemical contained in the main tank and the sub tank during the double tank operation mode, injecting a flushing chemical into each tank and circulating the flushing chemical, and then draining the flushing chemical; and
a liquid preparation operation of supplying a new chemical to the main tank and the sub tank, and
the operation (c) includes:
a flushing operation of draining a chemical contained in the pre-tank, injecting a flushing chemical into the pre-tank and circulating the flushing chemical, and draining the flushing chemical; and
a liquid preparation operation of supplying a new chemical to the pre-tank.

20. The liquid exchange method of claim 19, wherein the operation (b) further includes a liquid preparation operation of supplying a new chemical to the recovery tank after flushing of the recovery tank is completed,
when the operation (b) is completed, the three tank operation mode is switched regardless of the start of the operation (c),
the operation (c) proceeds after the completion of the operation (b) or immediately before a lifetime of the chemical is reached, and
in the double tank operation mode, the chemical used in the substrate processing apparatus is recovered to the recovery tank, and in the single tank operation mode, the chemical used in the substrate processing apparatus is not recovered to the recovery tank and is treated as wastewater.
